(19) United States
(12) Patent Application Publication
(10) Pub. No.: US 2022/0125012 A1
(43) Pub. Date: Apr. 28, 2022

(54) PET RETRIEVE DEVICE AND PET RETRIEVE METHOD

(71) Applicant: Zhiye Wang, Shanwei (CN)

(72) Inventor: Zhiye Wang, Shanwei (CN)

(21) Appl. No.: 17/570,347

(22) Filed: Jan. 6, 2022

(51) Int. Cl. A01K 11/00; H05K 5/06; H05K 5/00

(52) U.S. Cl. CPC A01K 11/008; H02J 7/0042; H05K 5/0086; H05K 5/06

(57) ABSTRACT

The present disclosure discloses a pet retrieve device, including a housing subassembly which is a hollow cavity; a circuit board and a battery fixedly arranged in the housing subassembly; a positioning chip arranged on the circuit board; a button and a charging interface which are arranged on the circuit board and penetrates through the housing subassembly; a lamp strip arranged in the housing subassembly, light emitted by the lamp strip being transmitted through the housing subassembly; and a two-dimensional code arranged on a surface of the housing subassembly. A one-to-one correspondence webpage can be opened by scanning the two-dimensional code, and the webpage displays preset pet information. The present disclosure discloses a pet retrieve method. The present disclosure can increase the possibility of retrieving a pet to a certain extent.

### TECHNICAL FIELD

The present disclosure relates to the technical field of pet retrieve devices, specifically to a pet retrieve device and a pet retrieve method.

### BACKGROUND

With the improvement of people's living standard, more and more pets are raised at home mainly by young people and the elder people. However, in real life, more and more pets are lost. After pets are lost, on the one hand, some pets pose a threat to the surrounding people, and on the other hand, it is extremely difficult for pet owners to find pets. There is no particularly effective retrieve way. Pets are searched generally by networks, posting advertisements, and the like. This method has a limited effect and requires a lot of energy and time for the pet owner. At present, after a pet is lost, the pet owner cannot retrieve the pet quickly and effectively. At the same time, there is also a problem that an adopter cannot find the pet owner in time. Therefore, in view of the shortcomings in the actual production and implementation of the above-mentioned solutions, the shortcomings are corrected and improved. Meanwhile, in line with the good spirit and concept, under the assistance of professional knowledge and experience, after thinking and testing in many ways, this design is created. Therefore, a pet retrieve device and a retrieve method are provided, so as to solve the above-mentioned problems.

### SUMMARY

One of the purposes of the present disclosure is to provide a pet retrieve device and a pet retrieve method, so as to solve the above-mentioned problems.

A pet retrieve device and a pet retrieve method of the present disclosure can be implemented by the following technical solutions:

A pet retrieve device of the present disclosure includes a housing subassembly which is a hollow cavity; a circuit board and a battery fixedly arranged in the housing subassembly; a positioning chip arranged on the circuit board; a button and a charging interface which are arranged on the circuit board and penetrates through the housing subassembly; a lamp strip arranged in the housing subassembly, light emitted by the lamp strip being transmitted through the housing subassembly; and a two-dimensional code arranged on a surface of the housing subassembly. A one-to-one correspondence webpage can be opened by scanning the two-dimensional code, and the webpage displays preset pet information.

In one implementation mode, the housing subassembly includes a main cavity and an upper cover; the upper cover is arranged on the main cavity; and the upper cover and the main cavity are connected through a screw structure, a fastener structure or a glued structure.

In one implementation mode, a connection part of the main cavity and the upper cover is provided with a waterproof ring, and a material of the waterproof ring is silica gel.

In one implementation mode, the housing subassembly is circular, elliptical, triangular, rectangular, rhombus-shaped, or hexagonal.

In one implementation mode, a side edge of the main cavity is provided with a button hole and a charging interface hole; and the button and the charging interface respectively penetrate through the housing subassembly through the button hole and the charging interface hole.

In one implementation mode, the positioning chip adopts a BeiDou Navigation Satellite System (BDS) positioning chip, a global positioning system (GPS) positioning chip, a global navigation satellite system (GNSS) positioning chip, or a galileo satellite navigation system (GSNS) positioning chip.

In one implementation mode, the battery is a rechargeable lithium battery, and the charging interface adopts a micro USB interface, a USB Type C interface, or a lightning interface.

A pet retrieve method includes: 101, logging in, by a pet owner, an account registered on an APP or website of an electronic terminal, and adding pet information; 102, binding the pet information with a two-dimensional code in a one-to-one correspondence manner; 103, after the two-dimensional code is scanned, opening a webpage on which the preset pet information is displayed; and 104, receiving, by the electronic terminal of the pet owner, a geographical location authorized by a mobile phone of a stranger.

In one implementation mode, the pet information includes a name of a pet, contact information of the pet owner, the gender of the pet, and the hobbies of the pet.

In one implementation mode, the webpage adopts an H5 webpage.

Compared with the existing art, the pet retrieve device and the retrieve method of the present disclosure has the beneficial effects as follows:

According to the pet retrieve device and the retrieve method of the present disclosure, the adopter scans the two-dimensional code on the housing subassembly with the mobile phone or an NFC module is sensed to open the one-to-one correspondence webpage, and the preset pet information is displayed on the webpage; the adopter finds the pet owner according to the contact information of the pet owner in the pet information; after receiving an authorization from the mobile phone of the adopter, the electronic terminal of the pet owner will receive the geographical location of the adopter; the pet owner can also roughly lock the location of the pet through the positioning chip, so that the possibility of retrieving a pet can be increased to a certain extent; meanwhile, by the arrangement of the lamp strip, it is convenient for the pet owner to find the location of the pet in dark places.

### BRIEF DESCRIPTION OF THE DRAWINGS

In order to explain the technical solutions of the embodiments of the present disclosure more clearly, the following will briefly introduce the accompanying drawings used in the embodiments. It should be understood that the drawings in the following description only illustrate some embodiments of the present disclosure and thus shall not be deemed as limiting the scope. Those of ordinary skill in the art can obtain other related drawings based on these drawings without creative work.

FIG. 1 is a schematic structural diagram of a pet retrieve device of the present disclosure;

FIG. 2 is a schematic structural diagram of the other side surface of the pet retrieve device of the present disclosure shown in FIG. 1;

FIG. 3 is a schematic exploded structural diagram of the pet retrieve device of the present disclosure shown in FIG. 1; and

FIG. 4 is a flowchart of a pet retrieve method of the present disclosure.

### REFERENCE SIGNS IN THE DRAWINGS

11: housing subassembly; 111: main cavity; 1111: button hole; 1112: charging interface hole; 112: upper cover; 12: circuit board; 121: battery cavity; 13: positioning chip; 14: battery; 15: button; 16: charging interface; 17: lamp strip; 18: two-dimensional code; and 19: lifting hole.

### DETAILED DESCRIPTION OF THE EMBODIMENTS

In order to make the objectives, technical solutions and advantages of the embodiments of the present disclosure clearer, the technical solutions in the embodiments of the present disclosure will be described clearly and completely below in combination with the drawings in the embodiments of the present disclosure. Obviously, the embodiments described herein are part of the embodiments of the present disclosure, not all the embodiments. The components of the embodiments of the present disclosure generally described and shown in the drawings here can be arranged and designed in a variety of different configurations.

Therefore, the following detailed description for the embodiments of the present disclosure provided in the accompanying drawings is not intended to limit the scope of the claimed present disclosure, but merely represents selected embodiments of the present disclosure. Based on the embodiments in the present disclosure, all other embodiments obtained by those of ordinary skill in the art without creative work shall fall within the protection scope of the present disclosure.

It should be noted that similar reference signs and letters indicate similar items in the following drawings. Therefore, once a certain item is defined in one drawing, it is unnecessary to be further defined and explained in the subsequent drawings.

In the description of the present disclosure, it should be noted that orientations or positional relationships indicated by the terms “upper”, “lower”, and the like are orientations or positional relationships as shown based on the drawings, or orientations or positional relationships where this disclosure product are usually placed, and are only for the purpose of facilitating and simplifying the description of the present disclosure instead of indicating or implying that devices or elements indicated must have particular orientations, and be constructed and operated in the particular orientations, so that these terms cannot be construed as limiting the present disclosure.

In addition, in the present disclosure, unless otherwise clearly defined and defined, the first feature being above or under the second feature may include that the first and second features are in direct contact, or may include that the first and second features are not in direct contact but in contact through other features between them. Moreover, the first feature being “on”, “at the upper side of”, and “on the upper surface of” the second feature includes that the first feature is right above and at the oblique upper side of the second feature, or only indicates that the horizontal height of the first feature is greater than that of the second feature. The first feature being “below”, “at the lower side of”, and “on the lower surface of” the second feature includes that the first feature is right below and at the oblique lower side of the second feature, or only indicates that the horizontal height of the first feature is less than that of the second feature.

In addition, the terms “horizontal”, “vertical”, and the like do not mean that the component is required to be absolutely horizontal or overhanging, but may be slightly inclined. For example, “horizontal” only means that its direction is more horizontal than “vertical”, and it does not mean that the structure must be completely horizontal, but can be slightly inclined.

In the description of the present disclosure, it should be also noted that unless otherwise explicitly defined and defined, the terms “arranged”, “coupled” and “connected” shall be understood broadly, and may be, for example, fixedly connected, or detachably connected, or integrally connected, or mechanically connected, or electrically connected, or directly connected, or indirectly connected through an intermediate medium, or interconnection between two elements. Those of ordinary skill in the art can understand the specific meanings of the above terms in the present disclosure according to specific situations.

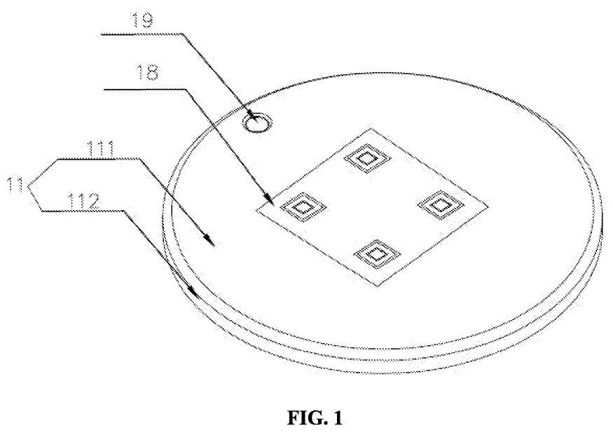

Referring to FIG. 1 to FIG. 3, a pet retrieve device of the present disclosure mainly includes a housing subassembly 11, a circuit board 12, a positioning chip 13, a battery 14, a button 15, a charging interface 16, a lamp strip 17, and a two-dimensional code 18. The housing subassembly 11 is a hollow cavity; the circuit board 12 and the battery 14 are fixedly arranged in the housing subassembly 11; the circuit board is electrically connected to the positioning chip 13, the battery 14, the button 15, the charging interface 16, and the lamp strip 17, respectively; the battery 14 provides electric energy for the circuit board 12; the positioning chip 13 is arranged on the circuit board 12 and can achieve real-time positioning; the button 15 and the charging interface 16 are arranged on the circuit board 12 and penetrate through the housing subassembly 11; the button 15 controls turning on or turning off of the lamp strip 17; the charging interface 16 charges the battery 14; the lamp strip 17 is arranged in the housing subassembly 11, and light emitted by the lamp strip 17 can be transmitted through the housing subassembly 11; the two-dimensional code 18 is arranged on a surface of the housing subassembly 11; the two-dimensional code 18 is scanned to open a one-to-one correspondence webpage; the webpage displays preset pet information; the pet information includes, but is not limited to, a name of a pet, contact information of a pet owner, the gender of the pet, and hobbies of the pet.

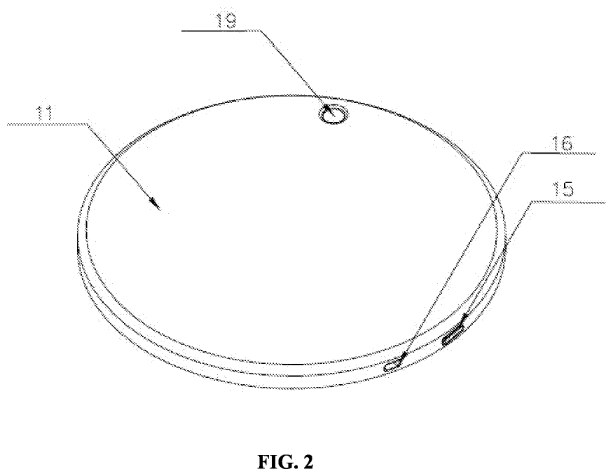

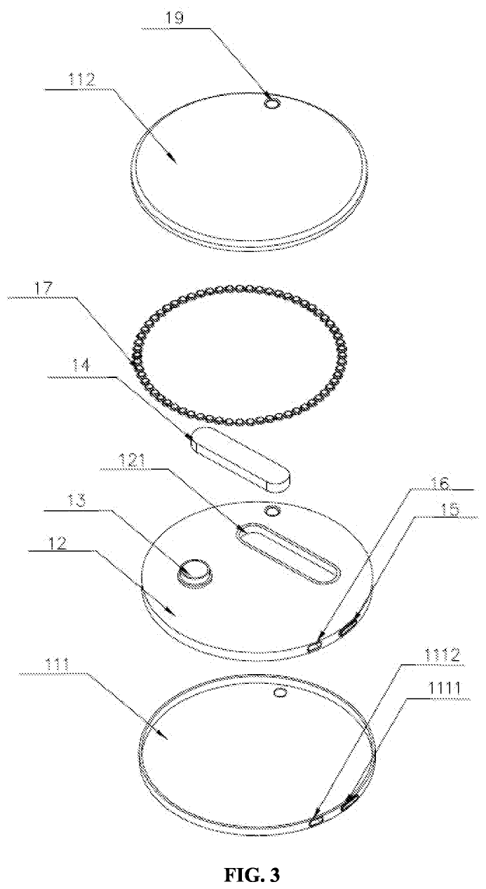

Referring to FIG. 2 and FIG. 3, the housing subassembly 11 includes a main cavity 111 and an upper cover 112; the main cavity 111 is a main body structure; the upper cover 112 is arranged on the main cavity 111; and the upper cover 112 and the main cavity 111 are connected through a screw structure, a fastener structure or a glued structure. In this embodiment, the main cavity 111 is connected with the upper cover 112 through the fastener structure. In order to improve the waterproof performance of the housing subassembly 11, a connection part of the main cavity 111 and the upper cover 112 is provided with a waterproof ring. Specifically, a material of the waterproof ring is silica gel. In this embodiment, the housing subassembly 11 is circular. In other embodiments, the housing subassembly 11 may also be elliptical, triangular, rectangular, rhombus-shaped, hexagonal, or of other polygons. In this embodiment, a side edge of the main cavity 111 is provided with a button hole 1111 and a charging interface hole 1112; and the button 15 and the charging interface 16 respectively penetrate through the housing subassembly 11 through the button hole 1111 and the charging interface hole 1112. In other embodiments, the upper cover 112 may also be provided with a button hole 1111 and a charging interface hole 1112.

Referring to FIG. 3, in this embodiment, the circuit board 12 is electrically connected to the positioning chip 13, the battery 14, the button 15, the charging interface 16, and the lamp strip 17. A control technology adopted is the existing art, so specific structures or model numbers are not repeatedly described here. In some embodiments, the circuit board 12 is provided with a near field communication (NFC) module; the electronic device senses the NFC module to open the one-to-one correspondence webpage; the webpage displays the pet information; and the pet information includes, but is not limited to, the name of the pet, the contact information of the pet owner, the gender of the pet, and the hobbies of the pet. In this embodiment, the circuit board 12 is further provided with a battery cavity 121, and a size of the battery cavity 121 is matched with that of the battery 14. The positioning chip 13 adopts a BeiDou Navigation Satellite System (BDS) positioning chip, a global positioning system (GPS) positioning chip, a global navigation satellite system (GNSS) positioning chip, or a galileo satellite navigation system (GSNS) positioning chip.

Referring to FIG. 3, in this embodiment, the battery 14 is a rechargeable lithium battery. Specifically, the battery 14 adopts a polymer lithium ion battery or a 18650 lithium battery. In this embodiment, the button 15 adopts a mechanical button. The button 15 is pressed to control the lamp strip 17 to be turned on or turned off. For better waterproof performance, a connection part of the button 15 and the housing subassembly 11 is provided with a waterproof ring. Specifically, a material of the waterproof ring is silica gel. In other embodiments, the button 15 may also be a touch-control button. The charging interface 16 may adopt a micro USB interface, a USB Type C interface, or a lightning interface. In this embodiment, the charging interface 16 adopts the micro USB interface. For better waterproof performance, a waterproof case is arranged in the charging interface 16. One end of the waterproof case is movably arranged on the housing subassembly 11 to prevent water from entering the housing subassembly 11 from the charging interface 16 to cause short circuit. In this embodiment, the lamp strip 17 adopts a ring light emitting diode (LED) lamp strip. By means of the light emitted by the lamp strip 17, the location of the pet can be found in a dark place.

Referring to FIG. 2, the two-dimensional code 18 is arranged on a surface of the housing subassembly 11 in a spray-coated manner or laser manner. In this embodiment, the two-dimensional code 18 is arranged on a lower surface of the main cavity 111 in the spray-coated manner. In other embodiments, the two-dimensional code 18 may also be arranged on an upper surface of the upper cover 112. In this embodiment, the housing subassembly 11 is further provided with a lifting hole 19. The lifting hole 19 penetrates through the upper and lower surfaces of the housing subassembly 11.

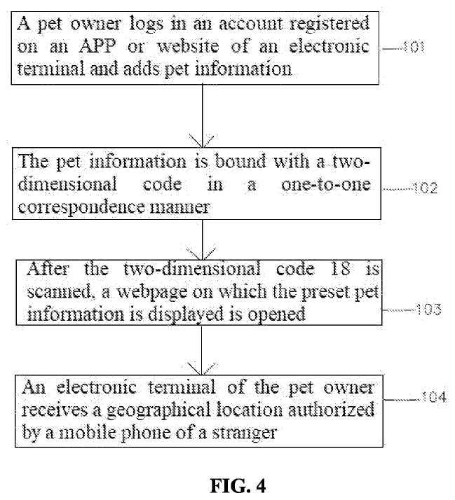

Referring to FIG. 4, a pet retrieve method of the present disclosure includes: 101, a pet owner logs in an account registered on an APP or website of an electronic terminal and adds pet information, the pet information including, but not limited to, a name of a pet, contact information of the pet owner, the gender of the pet, and hobbies of the pet; 102, the pet information is bound with the two-dimensional code 18 in a one-to-one correspondence manner; 103, after the two-dimensional code 18 is scanned, a webpage on which the preset pet information is displayed is opened, the pet information including, but not limited to, the name of the pet, the contact information of the pet owner, the gender of the pet, and the hobbies of the pet, wherein specifically, the webpage is an H5 webpage; and 104, an electronic terminal of the pet owner receives a geographical location authorized by a mobile phone of a stranger, a way of receiving the geographical location including one or more of APP, mailbox and short message.

It should be noted that according to the pet retrieve device and the retrieve method of the present disclosure, the adopter scans the two-dimensional code 18 with the mobile phone or the NFC module is sensed to open the one-to-one correspondence webpage; the preset pet information is displayed on the webpage; the adopter finds the pet owner according to the contact information of the pet owner in the pet information; after receiving an authorization from the mobile phone of the adopter, the electronic terminal of the pet owner will receive the geographical location of the adopter; the pet owner can also roughly lock the location of the pet through the positioning chip 13.

The technical features of the embodiments described above can be arbitrarily combined. In order to make the description concise, all possible combinations of various technical features in the above embodiments are not completely described. However, the combinations of these technical features should be considered as the scope described in the present specification as long as there is no contradiction in them.

The above-mentioned embodiments only express several implementation modes of the present disclosure, and their descriptions are more specific and detailed, but they cannot be understood as limiting the patent scope of the present disclosure. It should be noted that those of ordinary skill in the art can further make various transformations and improvements without departing from the concept of the disclosure, and these transformations and improvements all fall within the protection scope of the present disclosure. Therefore, the protection scope of the patent of the present disclosure shall be subject to the appended claims.

What is claimed is:

1. A pet retrieve device, comprising a housing subassembly which is a hollow cavity; a circuit board and a battery fixedly arranged in the housing subassembly; a positioning chip arranged on the circuit board; a button and a charging interface which are arranged on the circuit board and penetrates through the housing subassembly; a lamp strip arranged in the housing subassembly, light emitted by the lamp strip being transmitted through the housing subassembly; and a two-dimensional code arranged on a surface of the housing subassembly, wherein a one-to-one correspondence webpage may be opened by scanning the two-dimensional code, and the webpage displays preset pet information.

2. The pet retrieve device according to claim 1, wherein the housing subassembly comprises a main cavity and an upper cover; the upper cover is arranged on the main cavity; and the upper cover and the main cavity are connected through a screw structure, a fastener structure or a glued structure.

3. The pet retrieve device according to claim 2, wherein a connection part of the main cavity and the upper cover is provided with a waterproof ring, and a material of the waterproof ring is silica gel.

4. The pet retrieve device according to claim 2, wherein the housing subassembly is circular, elliptical, triangular, rectangular, rhombus-shaped, or hexagonal.

5. The pet retrieve device according to claim 2, wherein a side edge of the main cavity is provided with a button hole and a charging interface hole; and the button and the charging interface respectively penetrate through the housing subassembly through the button hole and the charging interface hole.

6. The pet retrieve device according to claim 1, wherein the positioning chip adopts a BeiDou Navigation Satellite System (BDS) positioning chip, a global positioning system (GPS) positioning chip, a global navigation satellite system (GNSS) positioning chip, or a galileo satellite navigation system (GSNS) positioning chip.

7. The pet retrieve device according to claim 1, wherein the battery is a rechargeable lithium battery, and the charging interface adopts a micro USB interface, a USB Type C interface, or a lightning interface.

8. A pet retrieve method, comprising: 101, logging in, by a pet owner, an account registered on an APP or website of an electronic terminal, and adding pet information; 102, binding the pet information with a two-dimensional code in a one-to-one correspondence manner; 103, after the two-dimensional code is scanned, opening a webpage on which the preset pet information is displayed; and 104, receiving, by the electronic terminal of the pet owner, a geographical location authorized by a mobile phone of a stranger.

9. The pet retrieve method according to claim 8, wherein the pet information comprises a name of a pet, contact information of the pet owner, the gender of the pet, and the hobbies of the pet.

10. The pet retrieve method according to claim 8, wherein the webpage adopts an H5 webpage.
